(19) United States
(12) Patent Application Publication
(10) Pub. No.: US 2019/0237692 A1
(43) Pub. Date: Aug. 1, 2019

(54) ACTIVE MATRIX SUBSTRATE AND X-RAY IMAGING PANEL INCLUDING THE SAME

(71) Applicant: SHARP KABUSHIKI KAISHA, Sakai City (JP)

(72) Inventors: MAKOTO NAKAZAWA, Sakai City (JP); KAZUHIDE TOMIYASU, Sakai City (JP); FUMIKI NAKANO, Sakai City (JP); YU NAKAMURA, Sakai City (JP)

(21) Appl. No.: 16/261,457

(22) Filed: Jan. 29, 2019

(30) Foreign Application Priority Data
Jan. 30, 2018 (JP) 2018-013286

(51) Int. Cl. H01L 51/44; H01L 27/30

(52) U.S. Cl. CPC H01L 51/448; H01L 27/286; H01L 27/308; H01L 27/307

(57) ABSTRACT

The invention provides a technique inhibiting entry of moisture to an active matrix substrate included in an X-ray imaging device.

An active matrix substrate includes, in each of the pixels, a photoelectric conversion element including a pair of electrodes and a semiconductor layer provided between the pair of electrodes, a first flattening film configured as an organic resin film and covering the photoelectric conversion element, and a first inorganic insulating film covering the first flattening film. The first flattening film and the first inorganic insulating film are provided to extend outside the pixel region. Outside the pixel region, the first flattening film is covered with the first inorganic insulating film to prevent exposure of the first flattening film.

### TECHNICAL FIELD

The present invention relates to an active matrix substrate and an X-ray imaging panel including the active matrix substrate.

### BACKGROUND ART

An X-ray imaging device conventionally includes an active matrix substrate having a photoelectric conversion element provided at each pixel and connected to a switching element. Patent Literature 1 discloses a technique inhibiting entry of moisture to such an X-ray imaging device. The X-ray imaging device according to Patent Literature 1 inhibits entry of moisture via an adhesive agent bonding a protective film for a phosphor layer provided on a photoelectric conversion substrate and the photoelectric conversion substrate. Specifically, the photoelectric conversion substrate, which adheres to the protective film covering an end of the phosphor layer, is provided with a groove. The groove receives the adhesive agent and the adhesive agent is thus unlikely to gather where the protective film and the photoelectric conversion substrate are bonded to each other, inhibiting entry of moisture via the adhesive agent.

### CITATION LIST

### Patent Literature

### Patent Literature 1: JP 6074111 BY

### SUMMARY OF INVENTION

### Technical Problem

The X-ray imaging device disclosed in Patent Literature 1 achieves a certain degree of inhibition of entry of moisture via the adhesive agent. The photoelectric conversion substrate is provided with a flattening film that is made of a photosensitive organic material and has an end exposed to outside air. The flattening film exerts higher moisture absorbency at higher temperature. Moisture may enter from the end of the flattening film exposed to outside air if outside air temperature rises to cause high humidity. Moisture entering a pixel via the flattening film is likely to cause leakage current of the photoelectric conversion element or the switching element provided at the pixel to lower photodetection accuracy.

The present invention provides a technique inhibiting entry of moisture to an active matrix substrate included in an X-ray imaging device.

### Solution to Problem

In order to solve the problem mentioned above, the present invention provides an active matrix substrate having a pixel region including a plurality of pixels, the active matrix substrate including in each of the pixels: a photoelectric conversion element including a pair of electrodes and a semiconductor layer provided between the pair of electrodes; a first flattening film configured as an organic resin film and covering the photoelectric conversion element; and a first inorganic insulating film covering the first flattening film; in which the first flattening film and the first inorganic insulating film are provided to extend outside the pixel region, and outside the pixel region, the first flattening film is covered with the first inorganic insulating film to prevent exposure of the first flattening film.

### Advantageous Effect of Invention

The present invention achieves inhibition of entry of moisture to an active matrix substrate included in an X-ray imaging device.

### BRIEF DESCRIPTION OF DRAWINGS

FIG. 1 is a pattern diagram of an X-ray imaging device according to a first embodiment;

FIG. 2 is a pattern diagram showing a schematic configuration of an active matrix substrate shown in FIG. 1;

FIG. 3 is an enlarged partial plan view of a pixel provided with a pixel of the active matrix substrate shown in FIG. 2;

FIG. 4 is a cross-sectional view taken along line A-A of the pixel shown in FIG. 3;

FIG. 5 is an enlarged partial cross-sectional view of the pixel and an end region in the active matrix substrate shown in FIG. 1;

FIG. 6 is an enlarged partial cross-sectional view of a pixel and an end region in an active matrix substrate according to a second embodiment;

FIG. 7 is an enlarged partial cross-sectional view of a pixel and an end region in an active matrix substrate according to a modification example of the second embodiment;

FIG. 8 is an enlarged partial cross-sectional view of a pixel and an end region in an active matrix substrate according to a third embodiment; and

FIG. 9 is a cross-cross-sectional view of the pixel and the end region in the active matrix substrate according to the first embodiment provided with a scintillator adhering thereto.

### DESCRIPTION OF EMBODIMENTS

According to an embodiment of the present invention, an active matrix substrate has a pixel region including a plurality of pixels and includes in each of the pixels: a photoelectric conversion element including a pair of electrodes and a semiconductor layer provided between the pair of electrodes; a first flattening film configured as an organic resin film and covering the photoelectric conversion element; and a first inorganic insulating film covering the first flattening film; in which the first flattening film and the first inorganic insulating film are provided to extend outside the pixel region, and outside the pixel region, the first flattening film is covered with the first inorganic insulating film to prevent exposure of the first flattening film (a first configuration).

Each of the pixels according to the first configuration is provided with the first flattening film covering the photoelectric conversion element and the first inorganic insulating film covering the first flattening film, and the first flattening film and the first inorganic insulating film extend to outside the pixel region. The first inorganic insulating film covers the first flattening film to prevent exposure outside the pixel region, so that the first flattening film is not exposed to outside air. The first flattening film configured as the organic resin film is not exposed to outside air, and moisture is thus unlikely to enter via the first flattening film even in a case where outside air temperature rises to cause high humidity. This configuration thus inhibits entry of moisture to the pixel. This configuration is unlikely to have leakage current of the photoelectric conversion element at the pixel to inhibit deterioration in photodetection accuracy due to such leakage current.

In the first configuration, optionally, the active matrix substrate further includes a second flattening film configured as an organic resin film and overlapped with at least part of the first inorganic insulating film, in which outside the pixel region, the second flattening film is overlapped in a planar view with an end of the first flattening film via the first inorganic insulating film (a second configuration).

According to the second configuration, the end of the first flattening film outside the pixel region is covered with the first inorganic insulating film and the second flattening film. This configuration more effectively inhibits entry of moisture to the first flattening film in comparison to the case where the end of the first flattening film is covered only with the first inorganic insulating film.

In the second configuration, optionally, the active matrix substrate further includes a second inorganic insulating film covering the second flattening film at least outside the pixel region, in which outside the pixel region, the second inorganic insulating film is overlapped in a planar view with the end of the first flattening film via the first inorganic insulating film, the second flattening film, and the second inorganic insulating film (a third configuration).

According to the third configuration, the end of the first flattening film is covered with the three insulating films, namely, the first inorganic insulating film, the second flattening film, and the second inorganic insulating film. This configuration more effectively inhibits entry of moisture to the second flattening film as well as to the first flattening film in comparison to the case where the second flattening film configured as the organic resin film is not covered with the second inorganic insulating film.

In the first configuration, optionally, the active matrix substrate further includes: a second flattening film configured as an organic resin film and overlapped with at least part of the first inorganic insulating film; and a second inorganic insulating film covering the second flattening film at least outside the pixel region; in which outside the pixel region, the second flattening film has an end disposed closer to the pixel region than an end of the first flattening film, and outside the pixel region, the second inorganic insulating film is overlapped in a planar view with the end of the flattening film via the first inorganic insulating film (a fourth configuration).

The fourth configuration includes the second flattening film configured as the organic resin film and overlapped with at least part of the first inorganic insulating film, and the second inorganic insulating film covering the second flattening film outside the pixel region. Outside the pixel region, the second flattening film is covered with the second inorganic insulating film and the end of the first flattening film is covered with the first inorganic insulating film and the second inorganic insulating film. The first flattening film and the second flattening film each configured as the organic resin film are thus not exposed to outside air, and moisture is unlikely to enter the first flattening film and the second flattening film even in a case where outside air temperature rises to cause high humidity.

In any one of the first to fourth configurations, the active matrix substrate may further include a metal film provided between an end of the first flattening film and the first inorganic insulating film covering the end of the first flattening film outside the pixel region (a fifth configuration).

According to the fifth configuration, the end of the first flattening film outside the pixel region is covered with the metal film and the first inorganic insulating film. Even if moisture enters via the first inorganic insulating film, the metal film inhibits the moisture from permeating the first flattening film and the pixel is unlikely to have entry of moisture via the first flattening film.

In the fifth configuration, optionally, the active matrix substrate further includes, in each of the pixels, a bias line connected to one of the pair of electrodes and configured to apply predetermined voltage to the one of the electrodes, in which the bias line and the metal film contain an identical metal material (a sixth configuration).

The sixth configuration enables formation of the metal film in an identical step of providing the bias line configured to apply predetermined voltage to the photoelectric conversion element provided at the pixel.

According to another embodiment of the present invention, an X-ray imaging panel includes: the active matrix substrate according to any one of the first to sixth configurations; a scintillator configured to convert applied X-rays to scintillation light; and a damp-proof material covering the scintillator; in which outside the pixel region of the active matrix substrate, the damp-proof material adheres to a surface of the active matrix substrate (a seventh configuration).

Each of the pixels according to the seventh configuration is provided with the first flattening film covering the photoelectric conversion element and the first inorganic insulating film covering the first flattening film, and the first flattening film and the first inorganic insulating film extend to outside the pixel region. The first inorganic insulating film covers the first flattening film to prevent exposure outside the pixel region, so that the first flattening film is not exposed to outside air. The first flattening film configured as the organic resin film is not exposed to outside air, and moisture is thus unlikely to enter via the first flattening film even in a case where outside air temperature rises to cause high humidity. This configuration thus inhibits entry of moisture to the pixel. This configuration is unlikely to have leakage current of the photoelectric conversion element at the pixel to inhibit deterioration in X-ray detection accuracy due to such leakage current.

Embodiments of the present invention will be described in detail below with reference to the drawings. Identical or corresponding portions in the drawings will be denoted by identical reference signs and will not be described repeatedly.

### First Embodiment

### (Configuration)

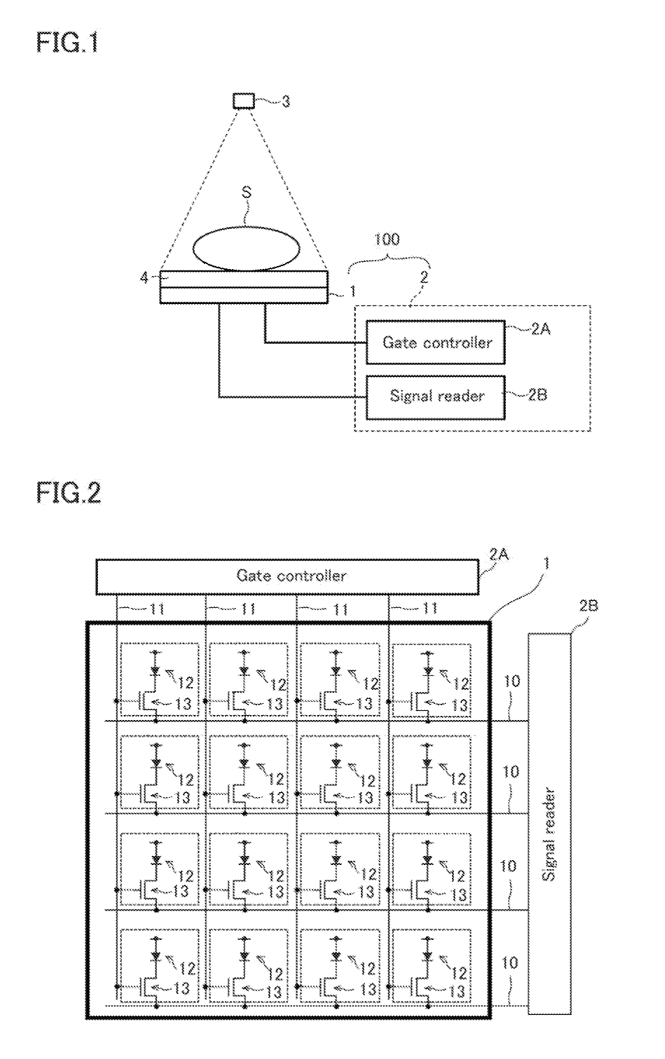

FIG. 1 is a pattern diagram of an X-ray imaging device including an active matrix substrate according to the present embodiment. An X-ray imaging device 100 includes an active matrix substrate 1 and a controller 2. The controller 2 includes a gate controller 2A and a signal reader 2B. There is provided an X-ray source 3 configured to apply X-rays to a target S. The X-rays having been transmitted through the target S are converted to fluorescence (hereinafter, referred to as scintillation light) by a scintillator 4 provided on the active matrix substrate 1. The X-ray imaging device 100 captures the scintillation light by means of the active matrix substrate 1 and the controller 2 to obtain an X-ray image.

FIG. 2 is a pattern diagram showing a schematic configuration of the active matrix substrate 1. As shown in FIG. 2, the active matrix substrate 1 is provided with a plurality of source lines 10 and a plurality of gate lines 11 crossing the source lines 10. The gate lines 11 are connected to the gate controller 2A, and the source lines 10 are connected to the signal reader 2B.

The active matrix substrate 1 includes TFTs 13 positioned at intersections between the source lines 10 and the gate lines 11 and each connected to a corresponding one of the source lines 10 and a corresponding one of the gate lines 11. A plurality of regions (hereinafter, referred to as pixels) defined with the source lines 10 and the gate lines 11 are each provided with a photodiode 12. The photodiode 12 at each of the pixels converts the scintillation light obtained by conversion from the X-rays having been transmitted through the target S to electric charges according to quantity of the scintillation light.

The gate lines 11 provided on the active matrix substrate 1 are sequentially switched into a selected state by the gate controller 2A, and the TFT 13 connected to the gate line 11 in the selected state turns into an ON state. When the TFT 13 turns into the ON state, a signal according to the electric charges obtained through conversion by the photodiode 12 is transmitted to the signal reader 2B via the source line 10.

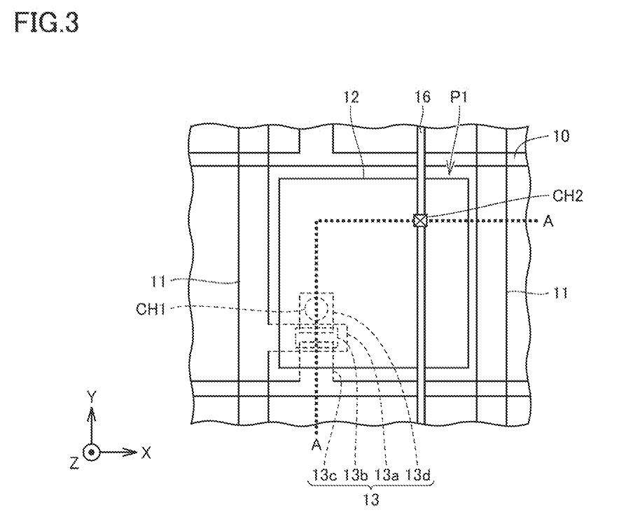

FIG. 3 is an enlarged plan view of part of pixels in the active matrix substrate 1 shown in FIG. 2.

As shown in FIG. 3, the photodiode 12 and the TFT 13 are provided in a pixel P1 surrounded with the gate lines 11 and the source lines.

The photodiode 12 includes a pair of electrodes and a photoelectric conversion layer provided between the pair of electrodes. The TFT 13 includes a gate electrode 13a provided integrally with the gate line 11, a semiconductor active layer 13b, a source electrode 13c integrated with the source line 10, and a drain electrode 13d. The drain electrode 13d and one of the electrodes of the photodiode 12 are connected to each other via a contact hole CH1.

There is provided a bias line 16 overlapped with the photodiode 12 in the pixel, and the photodiode 12 and the bias line 16 are connected to each other via a contact hole CH2. The bias line 16 is configured to supply the photodiode 12 with bias voltage.

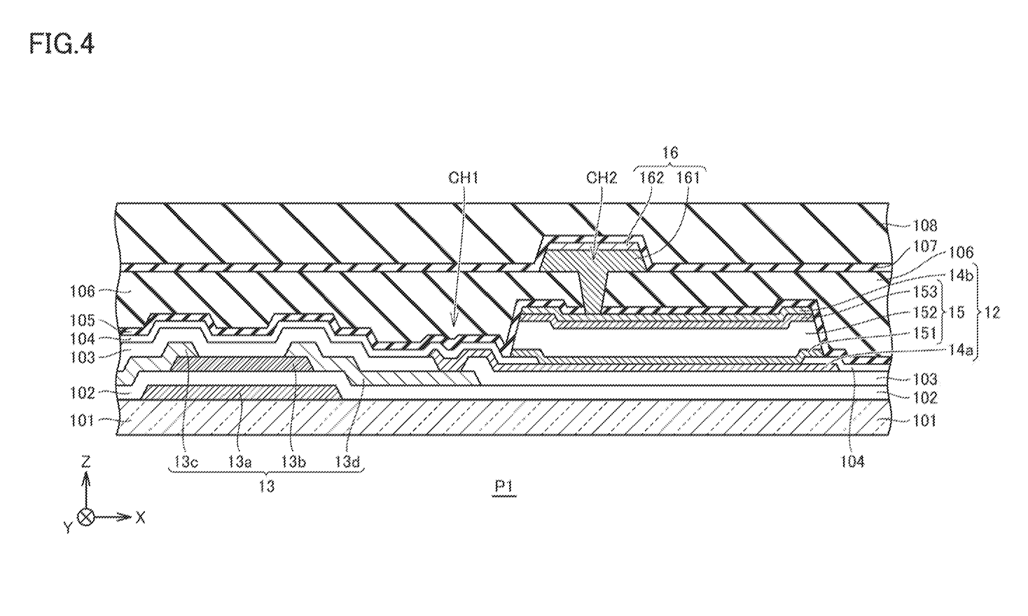

The pixel P1 will be described below in terms of a cross-sectional structure taken along line A-A. FIG. 4 is a cross-sectional view taken along line A-A of the pixel P1 shown in FIG. 3. FIG. 4 shows a substrate 101 provided thereon with the gate electrode 13a integrated with the gate line 11 (see FIG. 3), and a gate insulating film 102. The substrate 101 has an insulation property and is configured as a glass substrate or the like.

The gate electrode 13a and the gate line 11 according to the present example has a layered structure including two metal films. The two metal films may be made of tungsten (W) and tantalum (Ta) in the mentioned order from the bottom. In this case, the lower metal film and the upper metal film are preferred to be about 300 nm to 500 nm and about 30 nm to 100 nm in thickness, respectively. The gate electrode 13a and the gate line 11 are not limited to have such a two-layer structure, but may alternatively have a single layer or a plurality of layers including at least two layers. The material and thickness of the gate electrode 13a and the gate line 11 are merely exemplified and are not limited to the above exemplification.

The gate insulating film 102 covers the gate electrode 13a. The gate insulating film 102 according to the present example has a layered structure including two inorganic insulating films. The two inorganic insulating films may be made of silicon nitride (SiNₓ) and silicon oxide (SiOₓ) in the mentioned order from the bottom. In this case, the lower inorganic insulating film and the upper inorganic insulating film are preferred to be about 300 nm and about 50 nm in thickness, respectively. A thinner inorganic insulating film made of silicon nitride (SiNₓ) is less likely to deteriorate, so that the film is more preferred to be about 10 nm to 15 nm in thickness. The gate insulating film 102 is not limited to have such a two-layer structure, but may alternatively have a single layer or a plurality of layers including at least two layers. The material and the thickness of the gate insulating film 102 are not limited to the above exemplification.

The gate electrode 13a is provided thereabove, while the gate insulating film 102 is interposed therebetween, with the semiconductor active layer 13b, as well as the source electrode 13c and the drain electrode 13d connected to the semiconductor active layer 13b.

The semiconductor active layer 13b is disposed in contact with the gate insulating film 102. The semiconductor active layer 13b is made of an oxide semiconductor. The oxide semiconductor is exemplified by an amorphous oxide semiconductor containing indium (In), gallium (Ga), and zinc (Zn) at predetermined ratios. The semiconductor active layer 13b is preferred to be about 100 nm in thickness in this case. The material and the thickness of the semiconductor active layer 13b are not limited to the above exemplification.

The source electrode 13c and the drain electrode 13d are disposed on the gate insulating film 102 and are in contact with part of the semiconductor active layer 13b. The source electrode 13c according to the present example is integrated with the source line 10 (see FIG. 3). The source electrode 13c and the drain electrode 13d have a layered structure including three metal films. The three metal films may be made of titanium (Ti), aluminum (Al), and titanium (Ti) in the mentioned order from the bottom. The three layered films are preferred to be about 50 nm, about 300 nm, and about 50 nm, in the mentioned order from the bottom in this case. The source electrode 13c and the drain electrode 13d are not limited to have such a three-layer structure, but may alternatively have a single layer or a plurality of layers including at least two layers. The material and thickness of the source electrode 13c and the drain electrode 13d are not limited to the above exemplification.

A first insulating film 103 that is overlapped with the source electrode 13c and the drain electrode 13d is provided on the gate insulating film 102. The first insulating film 103 has the contact hole CH1 positioned above the drain electrode 13d. The first insulating film 103 according to the present example has a layered structure including two inorganic insulating films. The two inorganic insulating films may be made of silicon dioxide (SiO₂) and silicon nitride (SiN) in the mentioned order from the bottom. In this case, the lower inorganic insulating film and the upper inorganic insulating film are preferred to be about 300 nm and about 200 nm in thickness, respectively. The first insulating film 103 is not limited to have such a two-layer structure, but may alternatively have a single layer or a plurality of layers including at least two layers. The first insulating film 103 configured to have a single layer is made only of silicon dioxide (SiO₂). The material and thickness of the first insulating film 103 are not limited to the above exemplification.

One of the electrodes (hereinafter, called a lower electrode) 14a of the photodiode 12, and a second insulating film 104 is provided on the first insulating film 103. The lower electrode 14a is connected to the drain electrode 13d via the contact hole CH1.

The lower electrode 14a according to the present example has a layered structure including three metal films. The three metal films may exemplarily be made of titanium (Ti), aluminum (Al), and titanium (Ti) in the mentioned order from the bottom. The three layered films are preferred to be about 50 nm, about 300 nm, and about 50 nm in the mentioned order from the bottom in this case. The lower electrode 14a is not limited to have such a three-layer structure, but may alternatively have a single layer or a plurality of layers including at least two layers. The material and thickness of the lower electrode 14a are not limited to the above exemplification.

The second insulating film 104 is overlapped with part of the lower electrode 14a and has an opening positioned above the lower electrode 14a. The second insulating film 104 according to the present example is configured as an inorganic insulating film made of silicon dioxide (SiO₂). In this case, the second insulating film 104 is preferred to be about 300 nm to 500 nm in thickness. The material and the thickness of the second insulating film 104 are not limited to the above exemplification.

A photoelectric conversion layer 15 is provided on the lower electrode 14a, and the lower electrode 14a and the photoelectric conversion layer 15 are connected to each other via the opening provided in the second insulating film 104.

The photoelectric conversion layer 15 includes an n-type noncrystalline semiconductor layer 151, an intrinsic noncrystalline semiconductor layer 152, and a p-type noncrystalline semiconductor layer 153 layered in the mentioned order.

The n-type noncrystalline semiconductor layer 151 is made of amorphous silicon doped with an n-type impurity (e.g. phosphorus).

The intrinsic noncrystalline semiconductor layer 152 is made of intrinsic amorphous silicon. The intrinsic noncrystalline semiconductor layer 152 is provided in contact with the n-type noncrystalline semiconductor layer 151.

The p-type noncrystalline semiconductor layer 153 is made of amorphous silicon doped with a p-type impurity (e.g. boron). The p-type noncrystalline semiconductor layer 153 is provided in contact with the intrinsic noncrystalline semiconductor layer 152.

The n-type noncrystalline semiconductor layer 151, the intrinsic noncrystalline semiconductor layer 152, and the p-type noncrystalline semiconductor layer 153 according to the present example are preferred to be about 10 nm to 100 nm, about 200 nm to 2000 nm, and about 10 nm to 50 nm in thickness, respectively. The n-type noncrystalline semiconductor layer 151, the intrinsic noncrystalline semiconductor layer 152, and the p-type noncrystalline semiconductor layer 153 are not limited to the above exemplification in terms of the dopant and the thickness.

Another one of the electrodes (hereinafter, called an upper electrode) 14b of the photodiode 12 is provided on the p-type noncrystalline semiconductor layer 153. The upper electrode 14b is configured by a transparent conductive film exemplarily made of indium tin oxide (ITO). The upper electrode 14b is preferred to be about 100 nm in thickness in this case. The material and the thickness of the upper electrode 14b are not limited to the above exemplification.

A third insulating film 105 is provided on the second insulating film 104 so that the third insulating film 105 is separated each other on the photodiode 12. The third insulating film 105 according to the present example may be configured as an inorganic insulating film made of silicon nitride (SiN). The third insulating film 105 is preferred to be about 300 nm to 500 nm in thickness in this case. The material and the thickness of the third insulating film 105 are merely exemplified and are not limited to the above exemplification.

A fourth insulating film 106 serving as the first flattening film is provided on the third insulating film 105. The contact hole CH2 is positioned above the photodiode 12 and permeates the third insulating film 105 and the fourth insulating film 106. The fourth insulating film 106 according to the present example may be made of organic transparent resin such as acrylic resin or siloxane resin. The fourth insulating film 106 is preferred to be about 3.0 μm in thickness in this case. The material and the thickness of the fourth insulating film 106 are not limited to the above exemplification.

The bias line 16 is provided on the fourth insulating film 106. The bias line 16 is connected to the upper electrode 14b of the photodiode 12 in the contact hole CH2. The bias line 16 is connected to the controller 2 (see FIG. 1). The bias line 16 applies, to the upper electrode 14b, bias voltage received from the controller 2.

The bias line 16 according to the present example has a layered structure including a metal layer 161 and a transparent conductive layer 162. The metal layer 161 according to the present example has a layered structure including three metal films. The three metal films may be made of titanium (Ti), aluminum (Al), and titanium (Ti) in the mentioned order from the bottom. The three layered metal films are preferred to be about 50 nm, about 300 nm to 600 nm, and about 50 nm in the mentioned order from the bottom in this case. The transparent conductive layer 162 may be made of ITO or the like and is preferred to be about 100 nm in thickness. The bias line 16 may alternatively have a single layer or a plurality of layers including at least two layers. The material and the thickness of the bias line 16 are not limited to the above exemplification.

A fifth insulating film 107 that covers the bias line 16 is provided on the fourth insulating film 106. The fifth insulating film 107 according to the present example may be configured as an inorganic insulating film made of silicon nitride (SiNₓ). The fifth insulating film 107 is preferred to be about 200 nm to 500 nm in thickness in this case. The material and the thickness of the fifth insulating film 107 are merely exemplified and are not limited to the above exemplification.

The fifth insulating film 107 is covered with a sixth insulating film 108 serving as the second flattening film. The sixth insulating film 108 may be made of organic transparent resin such as acrylic resin or siloxane resin. The sixth insulating film 108 is preferred to be about 3.0 μm in thickness in this case. The material and the thickness of the sixth insulating film 108 are merely exemplified and are not limited to the above exemplification.

Each of the pixels P1 has the cross-sectional structure described above. Described next is a structure outside the entire pixel region of the active matrix substrate 1, specifically, a structure of an end region in the active matrix substrate 1.

FIG. 5 is an enlarged partial cross-sectional view of the pixel P1 and an end region P2 along a side of the active matrix substrate 1. In FIG. 5, components identical to those shown in FIG. 4 are denoted by identical reference signs. The end region P2 will be described below specifically in terms of the structure. FIG. 5 shows the section of the end region along one of the sides of the active matrix substrate 1 for convenience. The remaining sides are assumed to have end regions configured similarly.

As shown in FIG. 5, in the end region P2, the gate insulating film 102 is provided on the substrate 101, and the first insulating film 103 is provided on the gate insulating film 102. The second insulating film 104 is provided on the first insulating film 103, and the third insulating film 105 is provided on the second insulating film 104. The fourth insulating film 106 is provided on the third insulating film 105, and the fifth insulating film 107 is provided to cover the fourth insulating film 106. A end of the fourth insulating film 106 is at a position x1 located inside (closer to the pixel P1) a position x2 of an end of the fifth insulating film 107. The end of the fourth insulating film 106 is thus completely covered with the fifth insulating film 107.

The sixth insulating film 108 is provided on the fifth insulating film 107. A end of the sixth insulating film 108 is at a position x3 located between the position x1 of the end of the fourth insulating film 106 and the position x2 of the end of the fifth insulating film 107. The end of the fourth insulating film 106 is thus covered with the fifth insulating film 107 and the sixth insulating film 108.

The end of the fourth insulating film 106 configured as the organic resin film and covering the photodiode 12 is completely covered with the fifth insulating film 107 configured as the inorganic insulating film and the sixth insulating film 108 configured as the organic resin film so as not to be exposed to outside air. Even in a case where outside air temperature rises and moisture enters via the sixth insulating film 108, the moisture is unlikely to permeate the fifth insulating film 107 to be inhibited from entering the fourth insulating film 106. This configuration is unlikely to have leakage current of the photodiode 12 and the TFT 13 (see FIG. 4) at the pixel P1 to improve X-ray detection accuracy.

The insulating films provided in the end region P2 can be formed simultaneously with the insulating films provided at the pixel P1.

### (Operation of X-Ray Imaging Device 100)

The X-ray imaging device 100 shown in FIG. 1 will be described below in terms of its operation. The X-ray source 3 initially emits X-rays. The controller 2 applies predetermined voltage (bias voltage) to the bias line 16 (see FIG. 3). The X-rays emitted from the X-ray source 3 are transmitted through the target S and enter the scintillator 4. The X-rays having entered the scintillator 4 are converted to fluorescence (scintillation light) that subsequently enters the active matrix substrate 1. When the scintillation light enters the photodiode 12 provided at each of the pixels of the active matrix substrate 1, the photodiode 12 converts the scintillation light to electric charges according to quantity of the scintillation light. When the TFT 13 (see FIG. 3 and the like) turns into the ON state in accordance with gate voltage (positive voltage) transmitted from the gate controller 2A via the gate line 11, the signal reader 2B (see FIG. 2 and the like) reads, via the source line 10, a signal according to the electric charges obtained through conversion by the photodiode 12. The controller 2 then generates an X-ray image according to the read signal.

### Second Embodiment

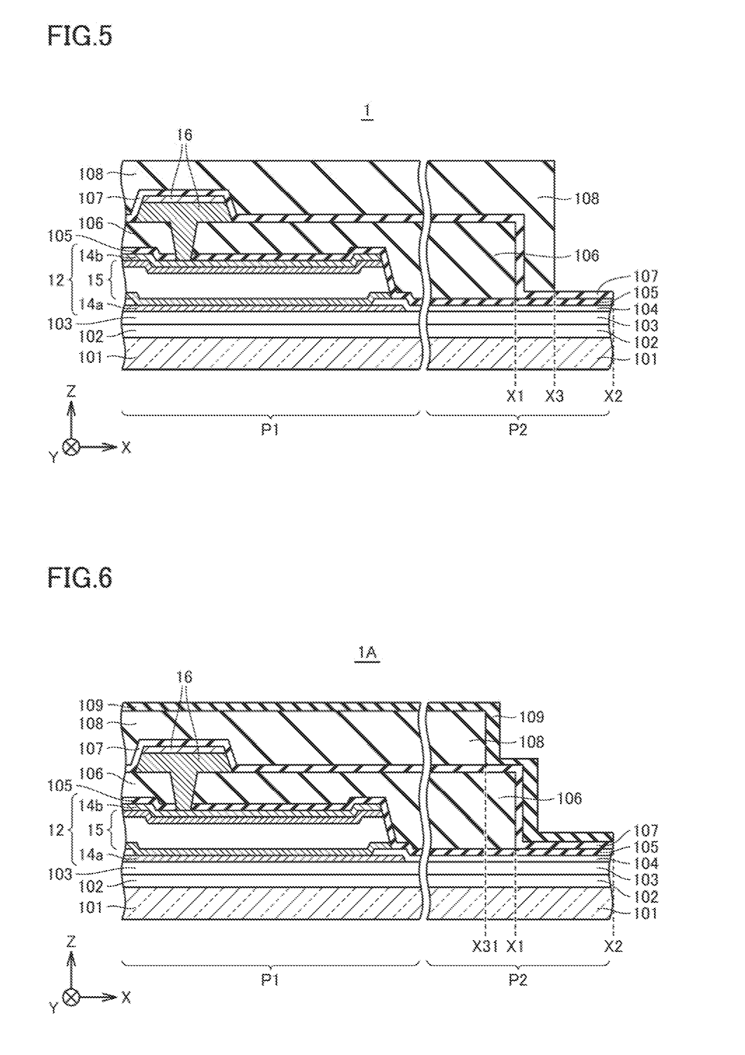

The present embodiment will refer to an end region P2 different in structure from the end region according to the first embodiment. FIG. 6 is an enlarged partial cross-sectional view of a pixel P1 and the end region P2 in an active matrix substrate 1A according to the present embodiment. In FIG. 6, components identical to those according to the first embodiment are denoted by identical reference signs. Components different from those of the first embodiment will be mainly described below.

As shown in FIG. 6, in the end region P2 of the active matrix substrate 1A, the end of the sixth insulating film 108 provided at a position x31 is inside (closer to the pixel P1) the end of the fourth insulating film 106 provided at the position x1. The pixel P1 and the end region P2 are further provided with a seventh insulating film 109 covering the sixth insulating film 108.

The seventh insulating film 109 according to the present example is configured as an inorganic insulating film made of silicon nitride (SiNₓ) and is exemplarily 150 nm to 300 nm in thickness, although the material and the thickness of the seventh insulating film 109 are not limited the exemplification.

A end of the seventh insulating film 109 is substantially at the position x2 where the end of the fifth insulating film 107 is, and the end of the sixth insulating film 108 is completely covered with the seventh insulating film 109. The end of the fourth insulating film 106 is covered with the fifth insulating film 107 and the seventh insulating film 109 each configured as the inorganic insulating film. The sixth insulating film 108 configured as the organic resin film is covered with the seventh insulating film 109, so that moisture is unlikely to permeate the sixth insulating film 108. The end of the fourth insulating film 106 configured as the organic resin film is covered with the two inorganic insulating films, namely, the fifth insulating film 107 and the seventh insulating film 109, so that moisture is less likely to permeate the fourth insulating film 106 in comparison to the first embodiment.

### Modification Example

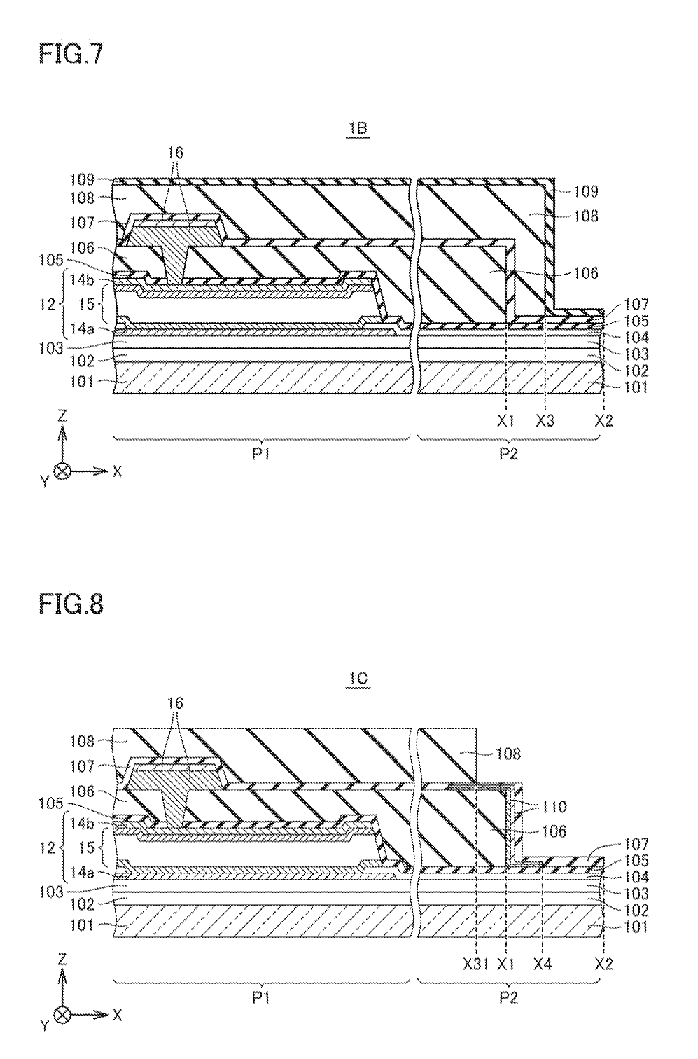

The end of the sixth insulating film 108 according to the second embodiment may alternatively be located between the position x1 of the end of the fourth insulating film 106 is and the position x2 of the end of the fifth insulating film 107. FIG. 7 is a partial cross-sectional view of a pixel P1 and an end region P2 in an active matrix substrate 1B according to the present modification example. In FIG. 7, components identical to those according to the second embodiment are denoted by identical reference signs.

As shown in FIG. 7, the position x3 of the end of the sixth insulating film 108 is located between the position x1 of the end of the fourth insulating film 106 and the position x2 of the end of the fifth insulating film 107. The end of the fourth insulating film 106 is thus covered with the fifth insulating film 107 configured as the inorganic insulating film, the sixth insulating film 108 configured as the organic resin film, and the seventh insulating film 109 configured as the inorganic insulating film. The end of the fourth insulating film 106 covering the photodiode 12 is covered with the three insulating films in this case. In comparison to the second embodiment, this configuration more effectively inhibits entry of moisture to the fourth insulating film 106 and achieves further improvement in X-ray detection accuracy.

### Third Embodiment

The second embodiment relates to the configuration in which the end of the fourth insulating film 106 is covered with the two inorganic insulating films, namely, the fifth insulating film 107 and the seventh insulating film 109. The present embodiment relates to a configuration in which the end of the fourth insulating film 106 is covered with a single inorganic insulating film and a metal film.

FIG. 8 is an enlarged partial cross-sectional view of a pixel P1 and an end region P2 in an active matrix substrate 1C according to the present embodiment. In FIG. 8, components identical to those according to the second embodiment are denoted by identical reference signs. Components different from those of the second embodiment will be mainly described below.

As shown in FIG. 8, in the pixel P1 and the end region P2 in the active matrix substrate 1C, the seventh insulating film 109 (see FIG. 6) is not provided on the sixth insulating film 108. In the end region P2, the fourth insulating film 106 and the fifth insulating film 107 interpose a metal film 110 covering the end of the fourth insulating film 106.

A end of the metal film 110 is at a position x4 located inside (closer to the pixel P1) the position x2 of the end of the fifth insulating film 107. The metal film 110 covers the end of the fourth insulating film 106 and is overlapped with part of the fifth insulating film 107 exposed to outside air.

The metal film 110 according to the present example has a two-layer structure made of the same materials for the bias line 16 provided at the pixel P1. The metal film 110 can thus be formed simultaneously in a step of forming the bias line 16 at the pixel P1.

The metal film 110 is made of the same materials for the bias line 16 in this case, but may alternatively be made of a metal material different from the metal material for the bias line 16. The metal film 110 may still alternatively have a single layer or a plurality of layers including at least two layers.

According to the present embodiment, the end of the fourth insulating film 106 configured as the organic resin film is covered with the metal film 110, and the metal film is covered with the fifth insulating film 107 configured as the inorganic insulating film. The metal film 110 is overlapped with part of the fifth insulating film 107 configured as the inorganic insulating film and exposed to outside air. Even if the fifth insulating film 107 allows moisture to enter via the portion exposed to outside air, the metal film 110 inhibits the moisture from permeating the fourth insulating film 106 covering the photodiode 12. In comparison to the second embodiment, this configuration more effectively inhibits entry of moisture to the pixel P1 and achieves further improvement in X-ray detection accuracy.

### Fourth Embodiment

The present embodiment refers to a module structure (X-ray imaging panel) including the active matrix substrate 1 according to the first embodiment and the scintillator 4 bonded to each other.

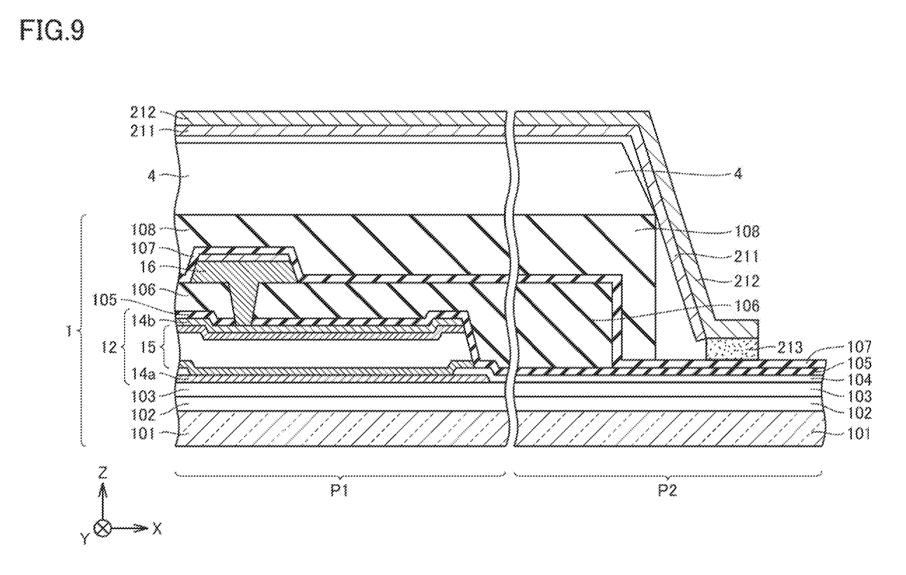

FIG. 9 is a cross-sectional view of the pixel P1 and the end region P2 in the active matrix substrate 1 with the scintillator 4 adhering thereto. In FIG. 9, components identical to those according to the first embodiment are denoted by identical reference signs. Components different from those of the first embodiment will be described below.

As shown in FIG. 9, the scintillator 4 is provided on a surface of the active matrix substrate 1, specifically, on the sixth insulating film 108.

The scintillator 4 is covered with a light reflector 211 having a sheet shape. The light reflector 211 reflects, toward the active matrix substrate 1, light directed to an X-ray incident end out of light emitted from the scintillator 4.

The light reflector 211 is covered with a damp-proof material 212 having a sheet shape, and the damp-proof material 212 is bonded to the surface of the active matrix substrate 1 by a sealant 213. Specifically, the damp-proof material 212 is bonded to the active matrix substrate 1 to cover the end of the sixth insulating film 108 in the end region P2. The damp-proof material 212 may contain aluminum (Al) or the like as a material.

As described above, the end of the fourth insulating film 106, which covers the photodiode 12 provided at each of the pixels P1 of the active matrix substrate 1, is covered with the fifth insulating film 107 and the sixth insulating film 108. The scintillator 4 is provided thereon with the damp-proof material 212 that covers the end of the sixth insulating film 108. The sixth insulating film 108 is thus not exposed to outside air. Even in a case where outside air temperature rises to cause high humidity, moisture is unlikely to enter via the sixth insulating film 108 to be inhibited from entering the pixel P1 for improvement in X-ray detection accuracy.

There has been described the module structure including the active matrix substrate 1 according to the first embodiment and the scintillator 4 bonded to each other. The scintillator 4 can similarly be bonded to any one of the active matrix substrates 1A to 1C according to the second embodiment, the modification example thereof, and the third embodiment.

The embodiments of the present invention described above are merely exemplified for implementation of the present invention. The present invention should not be limited to the above embodiments, and can be implemented with appropriate modifications to the above embodiments without departing from the purpose of the present invention.

(1) The end region P2 in the active matrix substrate according to the first or second embodiment may further be provided with the metal film 110 according to the third embodiment. The metal film 110 is disposed as in the third embodiment to cover the end of the fourth insulating film 106 configured as the organic resin film. This configuration more effectively inhibits entry of moisture from the end of the fourth insulating film 106, in comparison to the first and second embodiments.
(2) The second embodiment and the modification example thereof exemplify provision of the seventh insulating film 109 configured as the inorganic insulating film on the sixth insulating film 108 at the pixel P1. The seventh insulating film 109 has only to be provided to be overlapped in a planar view with the end of the fourth insulating film 106 at least in the end region P2.
(3) In the end region P2 in the active matrix substrate according to any one of the first to fourth embodiments, the end of the fourth insulating film 106 serving as the first flattening film has only to be covered at least with the fifth insulating film 107 configured as the inorganic insulating film. The end of the fourth insulating film 106 is not exposed to outside air even in such a configuration, to inhibit entry of moisture even in a case where outside air temperature rises to cause high humidity.

### CROSS REFERENCE TO RELATED APPLICATION

The present application claims priority under 35 U.S.C. § 119 to Japanese Patent Application No. 2018-013286, filed Jan. 30, 2018. The contents of this application are incorporated herein by reference in their entirety.

1. An active matrix substrate having a pixel region including a plurality of pixels,
the active matrix substrate comprising in each of the pixels:
a photoelectric conversion element including a pair of electrodes and a semiconductor layer provided between the pair of electrodes;
a first flattening film configured as an organic resin film and covering the photoelectric conversion element; and
a first inorganic insulating film covering the first flattening film; wherein
the first flattening film and the first inorganic insulating film are provided to extend outside the pixel region, and
outside the pixel region, the first flattening film is covered with the first inorganic insulating film to prevent exposure of the first flattening film.

2. The active matrix substrate according to claim 1, further comprising
a second flattening film configured as an organic resin film and overlapped with at least part of the first inorganic insulating film, wherein
outside the pixel region, the second flattening film is overlapped in a planar view with an end of the first flattening film via the first inorganic insulating film.

3. The active matrix substrate according to claim 2, further comprising
a second inorganic insulating film covering the second flattening film at least outside the pixel region, wherein
outside the pixel region, the second inorganic insulating film is overlapped in a planar view with the end of the first flattening film via the first inorganic insulating film, the second flattening film, and the second inorganic insulating film.

4. The active matrix substrate according to claim 1, further comprising:
a second flattening film configured as an organic resin film and overlapped with at least part of the first inorganic insulating film; and
a second inorganic insulating film covering the second flattening film at least outside the pixel region; wherein
outside the pixel region, the second flattening film has an end disposed closer to the pixel region than an end of the first flattening film, and
outside the pixel region, the second inorganic insulating film is overlapped in a planar view with the end of the flattening film via the first inorganic insulating film.

5. The active matrix substrate according to claim 1, further comprising a metal film provided between an end of the first flattening film and the first inorganic insulating film covering the end of the first flattening film outside the pixel region.

6. The active matrix substrate according to claim 5,
further comprising in each of the pixels
a bias line connected to one of the pair of electrodes and configured to apply predetermined voltage to the one of the electrodes, wherein
the bias line and the metal film contain an identical metal material.

7. An X-ray imaging panel comprising:
the active matrix substrate according to claim 1;
a scintillator configured to convert applied X-rays to scintillation light; and
a damp-proof material covering the scintillator; wherein
outside the pixel region of the active matrix substrate, the damp-proof material adheres to a surface of the active matrix substrate.
